(19) United States
(12) Patent Application Publication
(10) Pub. No.: US 2014/0063753 A1
(43) Pub. Date: Mar. 6, 2014

(54) ELECTRONIC MODULE, ELECTRONIC DEVICE, AND MOBILE UNIT

(71) Applicant: Seiko Epson Corporation, Tokyo (JP)

(72) Inventor: Taketo CHINO, Hokuto (JP)

(73) Assignee: Seiko Epson Corporation, Tokyo (JP)

(21) Appl. No.: 14/013,772

(22) Filed: Aug. 29, 2013

(30) Foreign Application Priority Data
Aug. 30, 2012 (JP) 2012-189631

(51) Int. Cl. H05K 9/00

(52) U.S. Cl. CPC H05K 9/00
USPC 361/729; 361/728

(57) ABSTRACT

An electronic module includes: a first substrate having first surface on which a first sensor element is provided and a second surface on which a circuit element is provided; a second substrate having a third surface on which a second sensor element is provided; a third substrate having a fifth surface on which a third sensor element is provided; a first connecting portion connecting the first substrate and the second substrate to each other; and a second connecting portion connecting the first substrate and the third substrate to each other. A shield layer is provided between the first sensor element and the circuit element.

### BACKGROUND

1. Technical Field

The present invention relates to an electronic module, an electronic device, and a mobile unit.

2. Related Art

According to a related art, an electronic module having an acceleration sensor element, angular velocity sensor element or the like as an example of a sensor for detecting attitudes or the like of an object is known. Such an electronic module is configured with three sensor elements provided on a flexible substrate, with the substrate being bent in such a way that detection axes of the three sensor elements become orthogonal to each other.

For example, JP-A-7-306047 discloses a structure in which a sensor element and a circuit element for processing a signal outputted from the sensor element are provided on each of three substrates, with two of the substrates standing up vertically on the one substrate, thus forming a rectangular column-like shape.

However, in the electronic module described in JP-A-7-306047, since a sensor element and a circuit element for performing a signal processing circuit are provided on each substrate, a large mounting area is required and the substrates are large-sized. Therefore, it is not easy to reduce the size of the electronic module. Moreover, electromagnetic noise generated from the circuit elements and heat may influence the operation of the sensor elements.

### SUMMARY

An advantage of some aspects of the invention is to solve at least a part of the problems described above, and the invention can be implemented as the following forms or application examples.

### Application Example 1

This application example is directed to an electronic module including: a first substrate having a first surface on which a first sensor element is provided and a second surface on which a circuit element is provided; a second substrate provided with a second sensor element; and a connecting portion which connects the first substrate and the second substrate with each other. The first substrate is provided with a shield layer between the first sensor element and the circuit element.

According to such an electronic module, the first sensor element and the second sensor element are provided, corresponding to the first substrate and the second substrate. Also, the circuit element which processes a signal outputted from each sensor element is provided on the second surface of the first substrate, which is arranged opposite to the first surface provided with the first sensor element via the shield layer. Thus, since a circuit element need not be provided on the second substrate, the substrate can be reduced in size. Moreover, since the circuit element is concentrated on the first substrate and is arranged opposite to the first sensor element via the shield layer, the influence of electromagnetic noise generated from the circuit element on each sensor element can be restrained.

### Application Example 2

In the electronic module according to the application example described above, it is preferable that the electronic module has a supporting portion having plural fixing surfaces, and the first substrate and the second substrate are fixed to each of the fixing surfaces.

According to such an electronic module, the first substrate and the second substrate connected to the first substrate via the connecting portion are fixed to the supporting portion. Thus, the first sensor element and the second sensor element provided on the first substrate and the second substrate have constant positions to each other and the direction of angular velocity and acceleration detected by each sensor element is made constant. Therefore, reliability of detection can be increased.

### Application Example 3

In the electronic module according to the application example described above, it is preferable that the supporting portion has an opening which accommodates one of the first sensor element, the second sensor element, and the circuit element.

According to such an electronic module, since the supporting portion has the opening, the first sensor element or the circuit element provided on the first substrate fixed to the supporting portion, or the second sensor element provided on the second substrate can be accommodated. As the first sensor element, the second sensor element, and the circuit element are accommodated in the opening, the first substrate and the second substrate can be fixed in close contact with the supporting portion.

### Application Example 4

In the electronic module according to the application example described above, it is preferable that the first sensor element is arranged on the side of the supporting portion and that the circuit element is arranged on the side opposite to the supporting portion.

According to such an electronic module, the first sensor element is arranged on the side of the supporting portion. Therefore, electromagnetic noise entering from outside the electronic module can be attenuated by the first substrate and propagation of the electromagnetic noise to the first sensor element can be restrained. Also, since the circuit element is arranged on the side opposite to the supporting portion, electromagnetic noise generated from the circuit element can be attenuated by the first substrate and propagation of the electromagnetic noise to the first sensor element can be restrained.

### Application Example 5

In the electronic module according to the application example described above, it is preferable that the electronic module has a pedestal for fixing the supporting portion thereon and that the circuit element is fixed to the pedestal.

According to such an electronic module, the circuit element is fixed to the pedestal on which the supporting portion is fixed.

Thus, heat generated from the circuit element can be transmitted to the pedestal and radiated there. The influence of heat generated from the circuit element on the first sensor element and the second sensor element can be restrained.

### Application Example 6

In the electronic module according to the application example described above, it is preferable that the circuit element has a first circuit portion provided on the second surface and a second circuit portion provided on the first circuit portion, and that a separation layer is provided between the first circuit portion and the second circuit portion.

In such an electronic module, the separation layer is provided between the first circuit portion and the second circuit portion of the circuit element. Thus, propagation of electromagnetic noise generated in the first circuit or the second circuit to the other circuit portion can be restrained.

### Application Example 7

In the electronic module according to the application example described above, it is preferable that the first circuit portion includes an analog circuit which amplifies an output signal from the first sensor element or the second sensor element, and that the second circuit portion includes a digital circuit which converts the signal amplified by the analog circuit to a digital signal.

In such an electronic module, the first circuit portion of the circuit element includes the analog circuit and the second circuit portion has the digital circuit.

Thus, compared with a first circuit portion including an analog circuit, the second circuit portion including the digital circuit with a greater amount of heat generation abuts on the pedestal and therefore heat can be transmitted to the pedestal and radiated there. Therefore, the influence of heat generation in the circuit element on each sensor element can be restrained.

### Application Example 8

This application example is directed to an electronic device including the electronic module described above.

According to such an electronic device, since the electronic device is equipped with the above electronic module, the influence of electromagnetic noise is retrained and detection accuracy in detecting attitudes or the like of the electronic device can be enhanced.

### Application Example 9

This application example is directed to a mobile unit including the electronic module described above.

According to such a mobile unit, since the mobile unit is equipped with the above electronic module, the influence of electromagnetic noise is retrained and detection accuracy in detecting attitudes or the like of the mobile unit can be enhanced.

### BRIEF DESCRIPTION OF THE DRAWINGS

The invention will be described with reference to the accompanying drawings, wherein like numbers reference like elements.

FIGS. 1A and 1B are perspective view schematically showing a configuration outline of an electronic module according to a first embodiment.

FIGS. 2A and 2B are expansion plans schematically showing amounting substrate of the electronic module according to the first embodiment.

FIG. 3 is a perspective view schematically showing the state where the mounting substrate of the electronic module according to the first embodiment is assembled, and a supporting portion which supports the mounting substrate.

FIGS. 4A to 4C are side views schematically showing a lateral side in the state where the mounting substrate shown in FIG. 3 is assembled.

FIGS. 5A to 5C are sides views schematically showing a lateral side in the state where the mounting substrate shown in FIG. 3 is fixed to the pedestal.

FIG. 6 illustrates the operation of a sensor element of the electronic module according to the first embodiment.

FIG. 7 is a schematic view showing an electronic device according to an example.

FIG. 8 is a schematic view showing an electronic device according to an example.

FIG. 9 is a schematic view showing an electronic device according to an example.

FIG. 10 is a schematic view showing a mobile unit according to an example.

### DESCRIPTION OF EXEMPLARY EMBODIMENTS

Hereinafter, embodiments of the invention will be described with reference to the drawings. In the drawings, the dimension and proportion of each component may be different from the actual component according to need, in order to show each component in a size large enough to be recognized in the drawings. Also, an XYZ orthogonal coordinate system is set and the positional relation of each part is described with reference to the XYZ orthogonal coordinate system. A predetermined direction in vertical plane is referred to as an X-axis direction. A direction orthogonal to the X-axis direction in the vertical plane is referred to as a Y-axis direction. A direction orthogonal to both the X-axis direction and the Y-axis direction is referred to as a Z-axis direction.

### First Embodiment

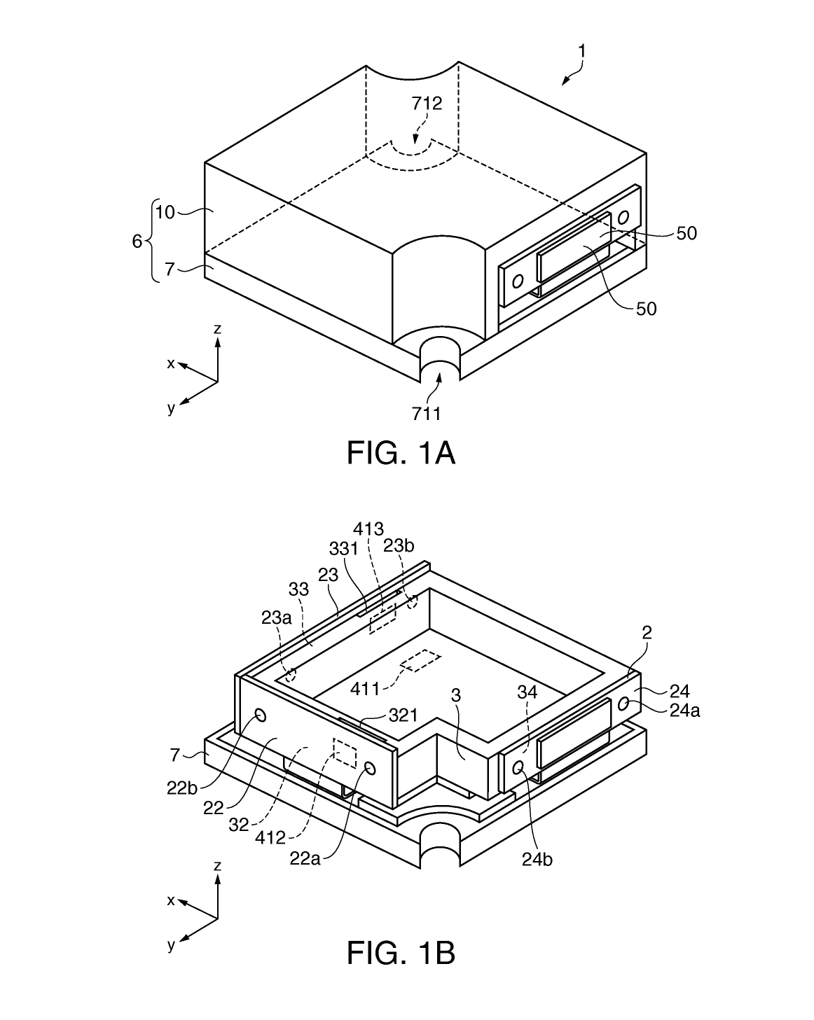

A module according to a first embodiment is shown in FIGS. 1A and 1B to FIG. 6.

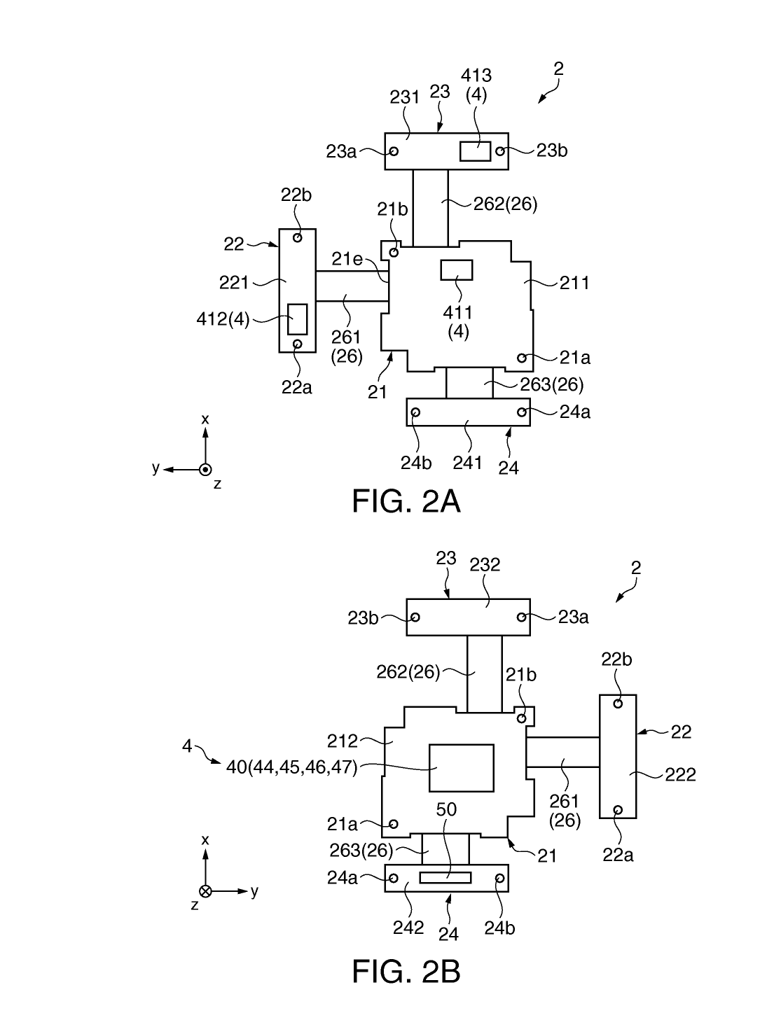

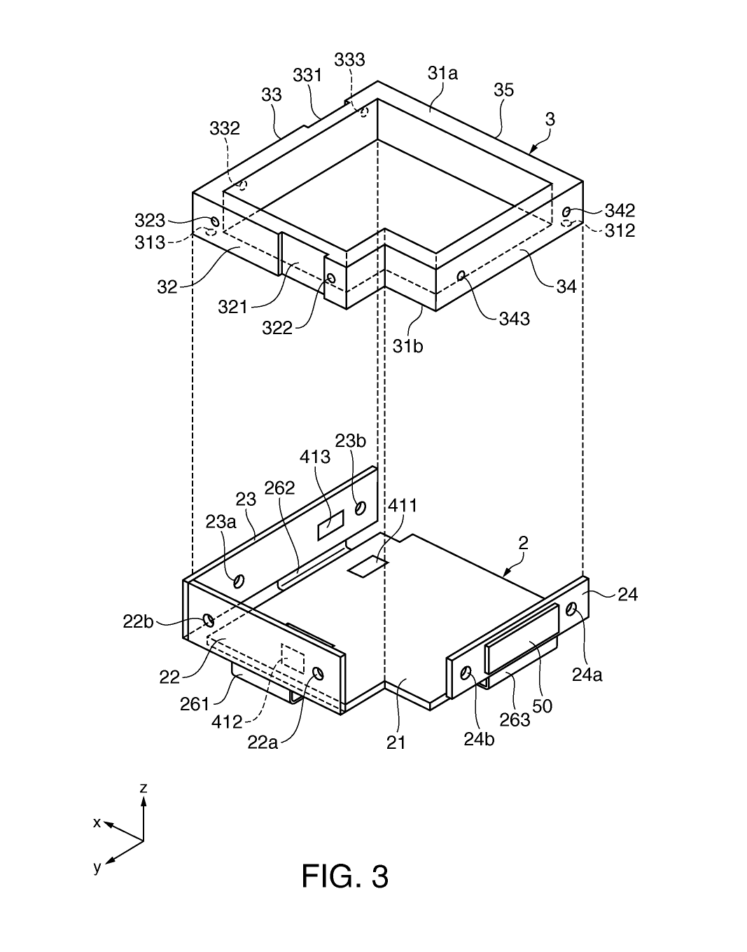

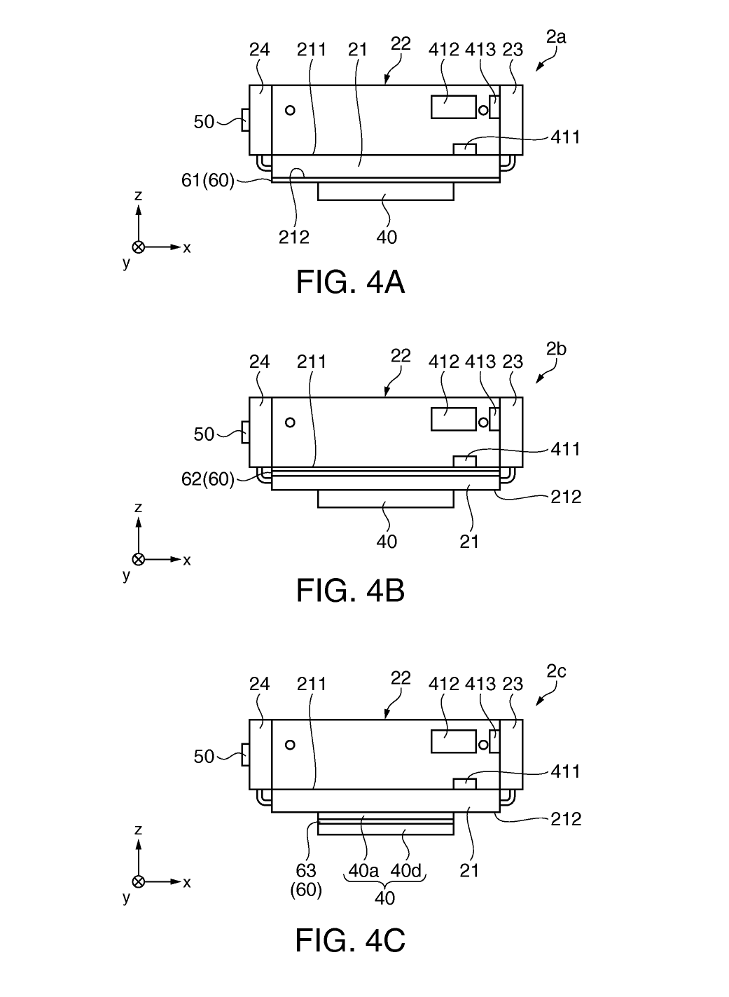

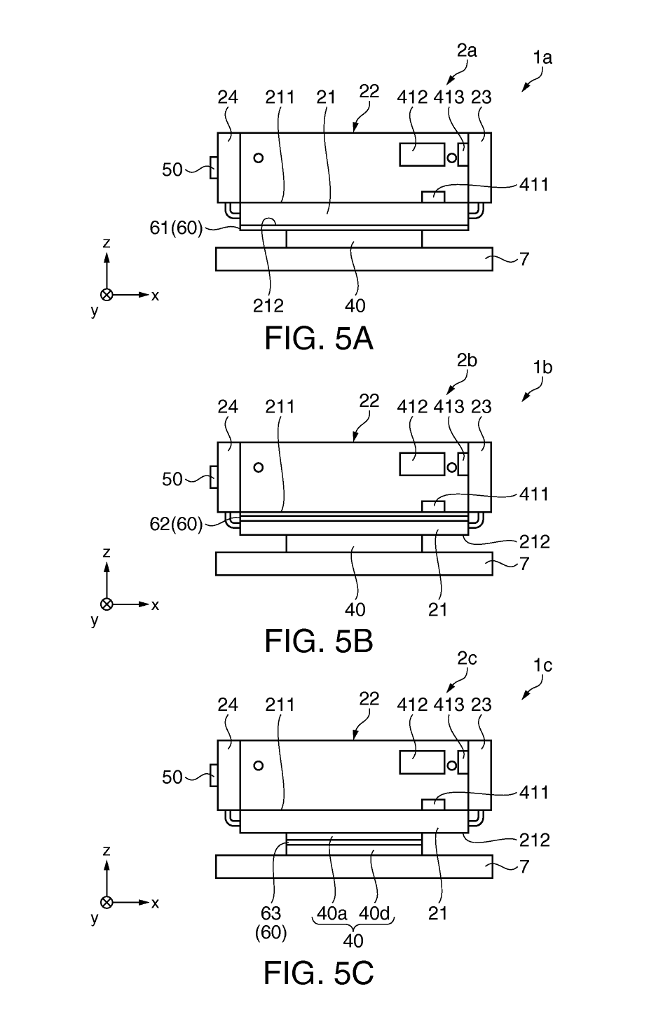

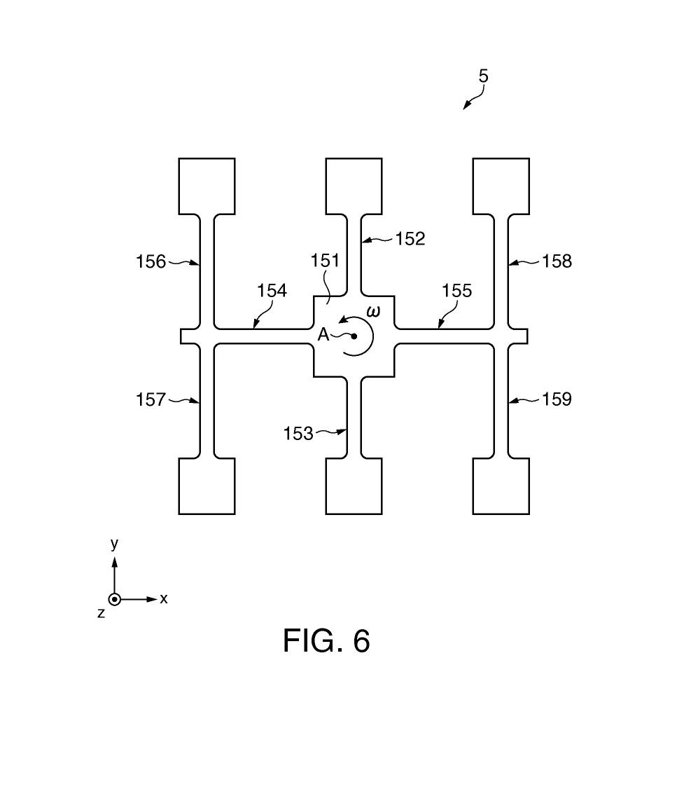

FIGS. 1A and 1B are perspective views schematically showing a configuration outline of an electronic module of this embodiment. FIGS. 2A and 2B are expansion plans schematically showing a mounting substrate provided in the electronic module shown in FIGS. 1A and 1B. FIG. 3 is a perspective view schematically showing the state where the mounting substrate shown in FIGS. 2A and 2B is assembled and a supporting portion which supports the mounting substrate. FIGS. 4A to 4C are side views schematically showing a lateral side in the state where the mounting substrate shown in FIGS. 2A and 2B is assembled. FIGS. 5A to 5B are side views schematically showing a lateral side in the state where the mounting substrate shown in FIGS. 2A and 2B is assembled and fixed to a pedestal. FIG. 6 illustrates the operation of a sensor element provided in the electronic module of this embodiment. For convenience of explanation, the supporting portion 3 is not shown in FIGS. 4A to 4C and FIGS. 5A to 5C.

An electronic module 1 of this embodiment shown in FIGS. 1A and 1B has a mounting substrate 2, a supporting portion 3 assembling and supporting the mounting substrate 2, and a casing 6 covering the mounting substrate 2 supported by the supporting portion 3.

The mounting substrate 2 has a first substrate 21 as a first substrate, and a second substrate 22, a third substrate 23 and a fourth substrate 24 as second substrates, and is supported by the supporting portion 3. The casing 6 has a pedestal 7 for fixing the mounting substrate 2 supported by the supporting portion 3, and a lid 10 covering the pedestal 7.

The electronic module 1 of this embodiment is described as an electronic module which detects acceleration or angular velocity, with the second substrate 22, the third substrate 23 and the fourth substrate 24 as plural second substrates connected to the first substrate 21 as a first substrate. As the second substrate, plural second substrates may be used depending on the acceleration to be detected or the direction in which angular velocity is to be detected. Hereinafter, the configuration of the electronic module 1 will be described in detail.

### Mounting Substrate 2

The mounting substrate 2 is a rigid-flexible substrate formed by a combination of the first substrate 21, the second substrate 22, the third substrate 23 and the fourth substrate 24 as rigid substrates that are hard and hardly deformable, and connecting portions 26 as flexible substrates that are soft and deformable. As such a mounting substrate 2, a known rigid-flexible substrate, for example, a rigid-flexible substrate formed by bonding a hard layer such as a glass epoxy substrate to both sides of a flexible substrate so that the hard layer part can be used as a rigid substrate, can be used.

FIG. 2A is a plan view showing the mounting substrate 2 in expanded state as viewed from above, that is, from the +Z-axis direction. FIG. 2B is a plan view showing the mounting substrate 2 in expanded state as viewed from the −Z-axis direction.

As shown in FIGS. 2A and 2B, the mounting substrate 2 is formed by the first substrate (first rigid substrate) 21, the second substrate (second rigid substrate) 22, the third substrate (third rigid substrate) 23, the fourth substrate (fourth rigid substrate) 24, arranged with space between each other, and the connecting portions (flexible substrates) 26 connecting these substrates.

Hereinafter, for convenience of explanation, a first surface 211 of the first substrate 21, a third surface 221 of the second substrate 22, a fifth surface 231 of the third substrate 23, and a seventh surface 241 of the fourth substrate 24 shown in FIG. 2A are referred to as “face-side mounting surfaces”. A second surface 212 of the first substrate 21, a fourth surface 222 of the second substrate 22, a sixth surface 232 of the third substrate 23, and an eighth surface 242 of the fourth substrate 24 shown in FIG. 2B are referred to as “back-side mounting surfaces”.

The connecting portions 26 include a first connecting portion 261 connecting the first substrate 21 with the second substrate 22, a second connecting portion 262 connecting the first substrate 21 with the third substrate 23, and a third connecting portion 263 connecting the first substrate 21 with the fourth substrate 24.

Each of the first connecting portion 261 to the third connecting portion 263 is flexible and can be easily deformed in planar directions.

Also, holes 21a, 21b are formed near both ends (two diagonal corners) of the first substrate 21. Also, holes 22a, 22b are formed near both ends of the second substrate 22. Holes 23a, 23b are formed near both ends of the third substrate 23. Holes 24a, 24b are formed near both ends of the fourth substrate 24.

These holes 21a to 23b are used to fix the first substrate 21 to the fourth substrate 24, to the supporting portion 3 (see FIGS. 1A and 1B). The holes in this embodiment include both a structure penetrating the substrate from one side to the other and a structure having an opening on one side of the substrate without penetrating the substrate to the other side.

Such a mounting substrate 2 can be deformed into the shape of a rectangular parallelepiped as shown in FIG. 1B and FIGS. 4A to 4C, by bending (curving) the connecting portions 26 (261 to 263).

Specifically, by bending the connecting portions 26 (261 to 263) in such a way that the face-side mounting surfaces (first surfaces) 211 to 241 of the first substrate 21 to the fourth substrate 24 face inside, the mounting substrate 2 can be deformed into the shape of a rectangular parallelepiped in which substrates next to each other are orthogonal to each other. In this state, the first substrate 21 forms a lower side 31b (see FIG. 3) and the second, third and fourth substrates 22, 23, 24 form lateral sides 32, 33, 34 (see FIG. 3). As shown in FIGS. 1A and 1B, the mounting substrate 2, thus deformed, is supported by and fixed to the supporting portion 3. In other words, the mounting substrate 2 is designed to be deformable to the shape corresponding to the supporting portion 3.

A conductor wire, not shown, is formed in the first substrate 21 to the fourth substrate 24 and the connecting portions 26 forming the mounting substrate 2. Plural electronic components 4, described later, are electrically connected to the first substrate 21 via this conductor wire.

As shown in FIGS. 2A and 2B, the plural electronic components 4 are mounted on the mounting substrate 2. On the mounting substrate 2, single axis detection-type sensors for measuring angular velocity or acceleration are provided as electronic components 4. In this embodiment, a first sensor element 411 is provided as a first sensor element on the first substrate 21. Also, a second sensor element 412 is provided on the second substrate 22 and a third sensor element 413 is provided on the third substrate 23, as second sensor elements. Moreover, as an electronic components 4, a circuit element (MCU (micro control unit)) 40 including an amplifier circuit 44 which amplifies output signals from the first to third sensor elements 411 to 413, an analog-digital converter circuit 45 which converts the analog signals amplified by the amplifier circuit 44 to digital signals, a controller 46 which performs desired control, and a non-volatile memory 47 such as EEPROM, is provided. Also, an interface connector 50 to output angular velocity or the like detected by the first sensor element 411 to the third sensor element 413 to outside of the electronic module 1 is provided on the fourth substrate 24.

Hereinafter, the arrangement of these electronic components 4 on the mounting substrate 2 will be described in detail.

On the first surface (face-side mounting surface) 211 of the first substrate 21, the first sensor element 411 which detects angular velocity or the like about the Z axis is provided. On the second surface (back-side mounting surface) 212, the circuit element 40 which processes output signals from the first to third sensor elements 411 to 413 is provided.

On the third surface (face-side mounting surface) 221 of the second substrate 22, the second sensor element 412 which detects angular velocity or the like about the Y axis is provided.

On the fifth surface (face-side mounting surface) 231 of the third substrate 23, the third sensor element 413 which detects angular velocity or the like about the X axis is mounted.

On the eighth surface (back-side mounting surface) 242 of the fourth substrate 24, the interface connector 50 is provided. This enables easy input and output of signals.

### Supporting Portion 3

As shown in FIG. 3, the supporting portion 3 is substantially in the shape of a rectangular parallelepiped and has an upper side 31a and a lower side 31b arranged opposite each other, and four lateral sides 32, 33, 34, 35 connecting the upper and lower sides. In such a supporting portion 3, at least two lateral sides next to each other and the upper side 31a or the lower side 31b are formed orthogonally to each other. In this embodiment, each side is formed orthogonally to the sides next to the side.

The lower side 31b, the lateral side 33, and the lateral side 32 are sides where the first substrate 21 to the third substrate 23 with the first sensor element 411 to the third sensor element 413 mounted thereon are fixed (engaged), as described later. Therefore, by forming these three sides orthogonally to each other, the first sensor element 411 to the third sensor element 413 can be arranged accurately in an attitude such that detection axes A (see FIG. 6) of these sensor elements are orthogonal to each other.

Therefore, according to the electronic module 1, angular velocity or the like can be detected with high accuracy about each axis (x axis, y axis, and z axis).

### Lower Side 31b

The lower side 31b forms a fixing surface to fix (engage) the first substrate 21. The first substrate 21 is fixed to the lower side 31b in the state where the first surface 211 thereof faces toward the supporting portion 3 (inside). Specifically, the supporting portion 3 has two protrusions 312, 313 protruding from the vicinities of both ends (two diagonal corners) of the lower side 31b, and the holes 21a, 21b formed in the first substrate 21 are engaged with these protrusions 312, 313. Thus, the first substrate 21 is fixed to the lower side 31b, as shown in FIG. 1B.

The inside of the supporting portion 3 surrounded by the lateral sides 32, 35 facing each other and the lateral sides 33, 34 facing each other is hollow. Therefore, the first substrate 21 can be fixed to the supporting portion 3 without interference by the first sensor element 411 provided on the first surface 211 of the first substrate 21. The same applies in the case where the circuit element 40 is provided on the first surface 211.

### Lateral Side 32

The lateral side 32 forms a fixing surface to fix (engage) the second substrate 22. The second substrate 22 is fixed to the lateral side 32 in the state where the first connecting portion 261 is bent and where the third surface 221 faces the supporting portion 3 (inside). Specifically, the supporting portion 3 has two protrusions 322, 323 protruding from both ends of the lateral side 32, and the holes 22a, 22b formed in the second substrate 22 are engaged with these protrusions 322, 323. Thus, the second substrate 22 is fixed to the lateral side 32, as shown in FIG. 1B.

The supporting portion 3 also has a recessed portion 321 opened on the lateral side 32. This recessed portion 321 is formed corresponding to the position and outer shape of the second sensor element 412. In the state where the second substrate 22 is fixed to the lateral side 32, the second sensor element 412 is accommodated in the recessed portion 321. That is, the recessed portion 321 forms an escape portion to prevent the supporting portion 3 and the second sensor element 412 from contacting each other. As such a recessed portion 321 is formed, the influence of electromagnetic noise on the second sensor element 412 from outside the electronic module 1 can be restrained by providing the second sensor element 412 on the side of the supporting portion 3. Also, the inner space of the supporting portion 3 can be effectively utilized and the electronic module 1 can be reduced in size.

### Lateral Side 33

The lateral side 33 forms a fixing surface to fix the third substrate 23. The third substrate 23 is fixed to the lateral side 33 in the state where the second connecting portion 262 is bent and where the fifth surface 231 faces toward the supporting portion 3 (inside). Specifically, the supporting portion 3 has two protrusions 332, 333 protruding from both ends of the lateral side 33, and the holes 23a, 23b formed in the third substrate 23 are engaged with these protrusions 332, 333. Thus, the third substrate 23 is fixed to the lateral side 33, as shown in FIG. 1B.

The supporting portion 3 also has a recessed portion 331 opened on the lateral side 33. This recessed portion 331 is formed corresponding to the position and outer shape of the third sensor element 413. In the state where the third substrate 23 is fixed to the lateral side 33, the third sensor element 413 is accommodated in the recessed portion 331. That is, the recessed portion 331 forms an escape portion to prevent the supporting portion 3 and the third sensor element 413 from contacting each other. As such a recessed portion 331 is formed, the influence of electromagnetic noise on the third sensor element 413 from outside the electronic module 1 can be restrained by providing the third sensor element 413 on the side of the supporting portion 3. Also, the inner space of the supporting portion 3 can be effectively utilized and the electronic module 1 can be reduced in size.

### Lateral Side 34

The lateral side 34 forms a fixing surface to fix the fourth substrate 24. The fourth substrate 24 is fixed to the lateral side 34 in the state where the third connecting portion 263 is bent and where the seventh surface 241 as a face-side mounting surface faces toward the supporting portion 3 (inside).

In other words, the fourth substrate 24 is fixed to the lateral side 34 in the state where the connector 50 is exposed outside the electronic module 1.

Specifically, the supporting portion 3 has two protrusions 342, 343 protruding from both ends of the lateral side 34, and the holes 24a, 24b formed in the fourth substrate 24 are engaged with these protrusions 342, 343. Thus, the fourth substrate 24 is fixed to the lateral side 34, as shown in FIG. 1B.

The material forming the supporting portion 3 is not particularly limited. However, hard materials are preferable in order to prevent deformation, for example, when external pressure is applied. Such materials may be, for example, various metals such as iron (Fe), nickel (Ni), copper (Cu), and aluminum (Al), or an alloy or intermetallic compound containing at least one of these metals, or oxides of these metals and the like. Among them, the alloys may be, for example, stainless steel, Inconel, and various aluminum-based alloys such as duralumin.

### Shield Layer 60

FIGS. 4A to 4C show sides views of the mounting substrate 2 assembled in the shape of a rectangular parallelepiped shown in FIG. 3, as viewed from the +Y-axis direction. On mounting substrates 2a, 2b shown in FIGS. 4A and 4B, a shield layer 60 (61, 62) electrically grounded between the first sensor element 411 provided on the first surface 211 of the first substrate 21 and the circuit element 40 provided on the second surface 212, that is, connected to the ground, is provided.

In the mounting substrate 2a shown in FIG. 4A, the shield layer 61 (60) is provided on the second surface 212 of the first substrate 21, and the circuit element 40 is provided on the side opposite to the second surface 212 via the shield layer 61. Although not shown, wires penetrating the shield layer 61 and connecting the circuit element 40 with the first sensor element 411 to the third sensor element 413 are provided in the mounting substrate 2a.

In the mounting substrate 2b shown in FIG. 4B, the shield layer 62 (60) is provided inside the first substrate 21 between the first surface 211 of the first substrate 21 and the second surface 212, and the circuit element 40 is provided on the side of the second surface 212 of the first substrate 21.

With respect to the mounting substrate 2a, though an example of providing the shield layer 61 on the second surface 212 is described, the shield layer 61 may also be provided between the first sensor element 411 and the first surface 211.

The circuit element 40 is equipped with a so-called digital circuit which carries out digital processing of signals outputted from the first to third sensor elements 411 to 413 in order to output these signals to outside the electronic module 1. Therefore, in some cases, electromagnetic noise may be generated from the circuit element 40 due to the operation of the digital circuit.

In the electronic module 1 having such mounting substrates 2a, 2b, the resulting noise can be cut off by the shield layer 60 and entry of the electromagnetic noise into very weak signals outputted from the first to third sensor elements 411 to 413 can be restrained.

The very weak signals outputted from the first to third sensor elements 411 to 413 are so-called analog signals and susceptible to the influence of electromagnetic noise. Therefore, as the electromagnetic noise generated from the circuit element 40 is cut off by the shield layer 60, the influence of the electromagnetic noise can be restrained.

Meanwhile, in amounting substrate 2c shown in FIG. 4C, the circuit element 40 is provided on the second surface 212 of the first substrate 21. A shield layer 63 as a separation layer is provided inside the circuit element 40. A first circuit portion 40a (analog circuit portion) which includes the amplifier circuit 44 for the signals outputted from the first to third sensor elements 411 to 413 and processes analog signals, and a second circuit portion 40d (digital circuit portion) which includes the analog-digital converter circuit 45, the controller 46 and the memory 47 and processes digital signals, are provided via the shield layer 63.

In the electronic module 1 having such a mounting substrate 2c, since the shield layer 63 is provided inside the circuit element 40, entry of electromagnetic noise generated from the controller 46 or the like provided in the second circuit portion 40d, into the first circuit portion 40a, and the influence of the electromagnetic noise can be restrained.

The material forming the shield layer 60 is not particularly limited. However, various metals including materials with excellent shielding capability against electric fields and with high conductivity such as copper (Cu) and aluminum (Al), and materials with excellent shielding capability against magnetic fields and with high initial permeability such as permalloy, iron (Fe), and nickel (Ni), or an alloy or intermetallic compound containing at least one of these metals, may be used.

FIGS. 5A to 5C show electronic modules 1a to 1c in the state where the mounting substrates 2a to 2c described with reference to FIGS. 4A to 4C are attached to the pedestal 7. For convenience of explanation, the supporting portion 3 and the casing 10 are not shown.

As shown in FIGS. 5A to 5C, in the electronic modules 1a to 1c, the mounting substrates 2a to 2c supported by the supporting portion 3 are attached to the pedestal 7.

The mounting substrates 2a and 2b shown in FIGS. 5A and 5B are attached to the pedestal 7, with the circuit element 40 provided on the second surface 212 of the first substrate 21 and the pedestal 7 abutting against each other.

The mounting substrate 2c shown in FIG. 5C is attached to the pedestal 7, with the surface where the second circuit portion 40d of the circuit element 40 provided on the second surface 212 of the first substrate 21 and the pedestal 7 abutting against each other.

Thus, heat generated in the circuit element 40 can be radiated to the pedestal 7. The influence of the heat on the first to third sensor elements 411 to 413 can be restrained. Change in characteristics of each sensor element due to the heat can be restrained. Also, strain of the mounting substrate 2 to which the first substrate 21, the second substrate 22 and the third substrate 23 are joined can be restrained and misalignment of the detection axis of the sensor element provided on each substrate can be restrained.

### Sensor Element

Next, the structure of the first to third sensor elements 411 to 413 will be described. Each of the first to third sensor elements 411 to 413 has a vibrating piece 5. FIG. 6 is a plan view showing the structure of the vibrating piece 5. The case where the first to third sensor elements 411 to 413 are angular velocity sensors is described an example. The first to third sensor elements 411 to 413 are not limited to angular velocity sensors and may be acceleration sensors that detect acceleration applied to the sensors.

The vibrating piece 5 shown in FIG. 6 is made of quartz (piezoelectric material). The vibrating piece 5 has a base portion 151, a pair of vibrating arms for detection 152, 153 extending in the Y-axis direction from both sides of the base portion 151, a pair of connecting arms 154, 155 extending in the X-axis direction from both sides of the base portion 151, and respective pairs of vibrating arms for drive 156, 157, 158, 159 extending in the X-axis direction from both sides of the distal ends of the respective connecting arms 154, 155. A detection electrode (not shown) is formed on the surface of each of the vibrating arms for detection 152, 153. A drive electrode (not shown) is formed on the surface of the vibrating arms for drive 156, 157, 158, 159.

In such a vibrating piece 5, if an angular velocity ω about a normal A to the vibrating piece 5 is applied in the state where the vibrating arms for drive 156, 158 and the vibrating arms for drive 157, 159 are made to vibrate in the way of repeating moves toward and away from each other by applying a voltage to the drive electrodes, a Coriolis force is applied to the vibrating piece 5, exciting vibration of the vibrating arms for detection 152, 153. Then, by detecting, with the detection electrodes, strain of the vibrating arms for detection 152, 153 generated by the vibration of the vibrating arms for detection 152, 153, the angular velocity applied to the vibrating piece 5 can be found.

### Casing 6

Back to FIGS. 1A and 1B, the casing to protect the mounting substrate 2 will be described.

As shown in FIGS. 1A and 1B, the electronic module has a structure in which the mounting substrate 2 is surrounded by the casing 6. The casing 6 has the pedestal 7 for fixing the mounting substrate 2, and the lid (cap) 10 covering the mounting substrate 2 fixed to the pedestal 7.

### Pedestal 7

As shown in FIGS. 1A and 1B, the pedestal 7 is plate-shaped and has a substantially rectangular shape as viewed in a plan view.

At two diagonal corners of the pedestal 7, slots 711, 712 opening to the outer circumference (outer edge) are formed. These slots 711, 712 extend in the same direction as each other.

The material forming the pedestal 7 is not particularly limited. However, a material with good thermal conductivity (high thermal conductivity) is preferable. This enables radiation of heat emitted from the circuit element 40 provided on the mounting substrate 2 and enables restraint on the influence due to the heat on the first to third sensor elements 411 to 413, that is, change in vibrating characteristics of the vibrating piece 5 due to temperature change. Such a material may be, for example, a metal such as copper (Cu) or aluminum (Al), an alloy containing these metals, or a magnesium alloy, iron-based alloy, copper alloy or the like.

According to the above first embodiment, the following advantages can be achieved.

According to such an electronic module 1, the circuit element 40 which processes signals outputted from the first to third sensor elements 411 to 413 is provided via the shield layer 60 on the first substrate 21 where the first sensor element 411 is provided.

This eliminates the need to provide the circuit element 40 on the second substrate 22 and the third substrate 23 where the second sensor element 412 and the third sensor element 413 are provided. Therefore, the area (size) of the second substrate 22 and the third substrate 23 can be decreased.

Thus, the height of the second substrate 22 and the third substrate 23 standing up substantially vertically by bending the connecting portion 26 connecting to the first substrate 21 can be restrained. Reduction in size and height of the electronic module 1 can be realized.

Also, electromagnetic noise generated from the circuit element 40 can be cut off by the shield layer 60 and entry of the electromagnetic noise into signals outputted from the first to third sensor elements 411 to 413 can be restrained.

Moreover, since the shield layer 63 is provided between the first circuit portion 40a and the second circuit portion 40d of the circuit element 40, electromagnetic noise generated from the second circuit portion 40d can be cut off, and entry of the electromagnetic noise into a signal outputted from the first sensor element 411 and into the first circuit portion 40a amplifying the signal can be restrained.

Also, the first to third sensor elements 411 to 413 are provided on the inner side of the electronic module 1 where the supporting portion 3 is provided. The first sensor element 411 is surrounded by the pedestal 7 and the supporting portion 3. The second sensor element 412 and the third sensor element 413 are surrounded by the lid 10 and the supporting portion 3 (321, 331).

Therefore, electromagnetic noise generated outside the electronic module 1 is attenuated by the casing 6 and the first to third substrates 21 to 23 and the influence of the electromagnetic noise on the first to third sensor elements 411 to 413 can be restrained.

Thus, the electronic module 1 with a reduced size in which the influence of electromagnetic noise generated by the circuit element 40 is reduced can be provided.

### Examples

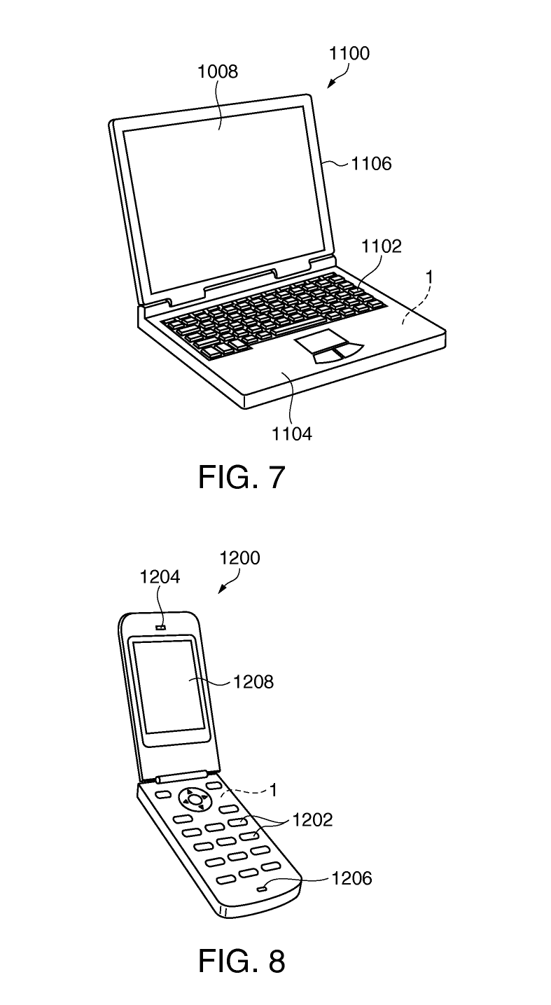

Next, examples of application of the electronic module 1 according to an embodiment of the invention will be described with reference to FIGS. 7 to 10.

### Electronic Devices

First, electronic devices to which the electronic module 1 according to the first embodiment of the invention is applied will be described with reference to FIGS. 7 to 9.

FIG. 7 is a perspective view showing a schematic configuration of a mobile (or notebook-type) personal computer as an electronic device having the electronic module according to the first embodiment of the invention. In FIG. 7, a personal computer 1100 includes a main body section 1104 having a keyboard 1102, and a display unit 1106 having a display section 1008. The display unit 1106 is supported in a bendable manner with respect to the main body section 1104 via a hinge structure. The electronic module 1 functioning as a gyro sensor or the like to detect the inclination of the personal computer 1100 is arranged inside the personal computer 1100. Even when electromagnetic noise is emitted from the personal computer 1100, the use of the electronic module 1 that is not likely to be affected by the electromagnetic noise enables stable detection of attitudes such as inclination.

FIG. 8 is a perspective view showing a schematic configuration of a mobile phone (including PHS) as an electronic device having the electronic module according to the first embodiment. In FIG. 8, a mobile phone 1200 has plural operation buttons 1202, and a receiving port 1204 and a transmitting port 1206. A display section 1208 is arranged between the operation buttons 1202 and the receiving port 1204. The electronic module 1 functioning as a gyro sensor or the like to detect the inclination and moving direction of the mobile phone 1200 is arranged inside the mobile phone 1200.

Even when electromagnetic waves due to communication are emitted from the mobile phone 1200, the use of the electronic module 1 that is not likely to be affected by the electromagnetic noise (electromagnetic waves) enables stable detection of the moving direction or the like.

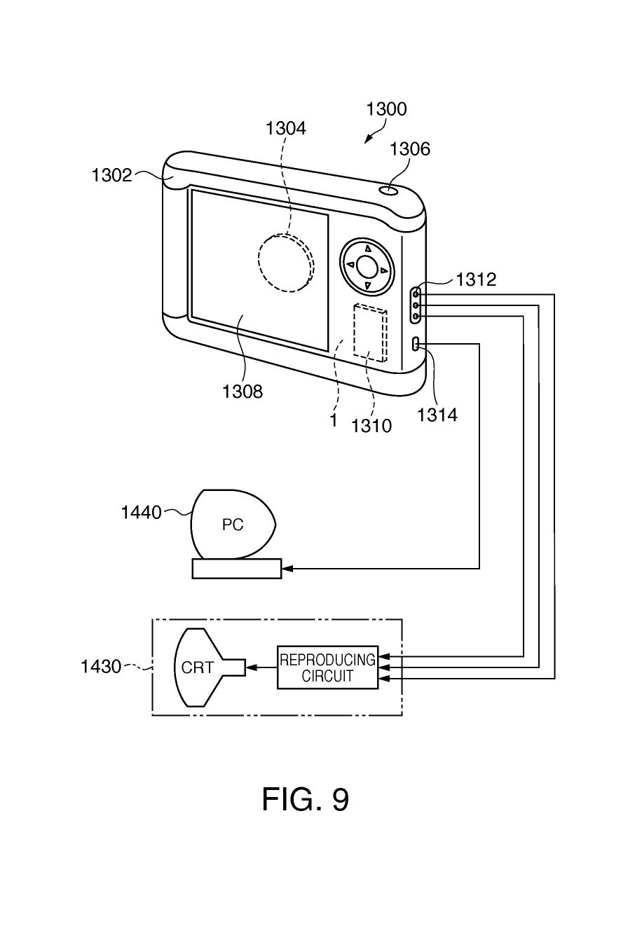

FIG. 9 is a perspective view showing a schematic configuration of a digital still camera as an electronic device having the electronic module according to the first embodiment of the invention. In FIG. 9, connections to external devices are simplified. Here, while a normal camera exposes a silver halide film to a light image of a subject, a digital still camera 1300 photoelectrically converts a light image of a subject with an image pickup element such as CCD (charge coupled device) and thus generates a picked-up image signal (image signal).

A display section 1308 is provided on the back side of a case (body) 1302 of the digital still camera 1300 and presents a display based on a picked-up image signal generated by the CCD. The display section 1308 functions as a viewfinder to show a subject as an electronic image. Also, a light receiving unit 1304 including an optical lens (image pickup system) and CCD is provided on the front side of the case 1302 (backside in FIG. 9).

As a cameraman checks a subject image shown in the display section 1308 and presses a shutter button 1306, a picked-up image signal generated by the CCD at that point is transferred to and stored in a memory 1310. Also, in the digital still camera 1300, a video signal output terminal 1312 and a data communication input/output terminal 1314 are provided on a lateral side of the case 1302. As illustrated, a television monitor 1430 is connected to the video signal output terminal 1312 and a personal computer 1440 is connected to the data communication input/output terminal 1314 according to need. Moreover, a predetermined operation causes the picked-up image signal stored in the memory 1310 to be outputted to the television monitor 1430 and the personal computer 1440. The electronic module 1 functioning as a gyro sensor or the like to detect the inclination of the digital still camera 1300 is arranged inside the digital still camera 1300.

Even when electromagnetic noise is emitted from a digital circuit which carries out photoelectric conversion as the digital still camera 1300 operates, the use of the electronic module 1 that is not likely to be affected by the electromagnetic noise enables stable detection of attitudes such as inclination.

The electronic module 1 according to the first embodiment of the invention can also be applied to electronic devices such as an ink jet ejection device (for example, ink jet printer), laptop personal computer, television set, video camera, video tape recorder, car navigation system, pager, electronic notebook (including those with communication functions), electronic dictionary, electronic calculator, electronic game device, word processor, workstation, TV phone, surveillance television monitor, electronic binocular, POS terminal, medical equipment (for example, electronic thermometer, sphygmomanometer, glucose meter, electrocardiograph, ultrasonic diagnosis device, and electronic endoscope), fishfinder, various measuring devices, gauges (for example, gauges in vehicles, aircraft and vessels), and flight simulator, as well as the personal computer (mobile personal computer) of FIG. 7, the mobile phone of FIG. 8, and the digital still camera of FIG. 9.

### Mobile Unit

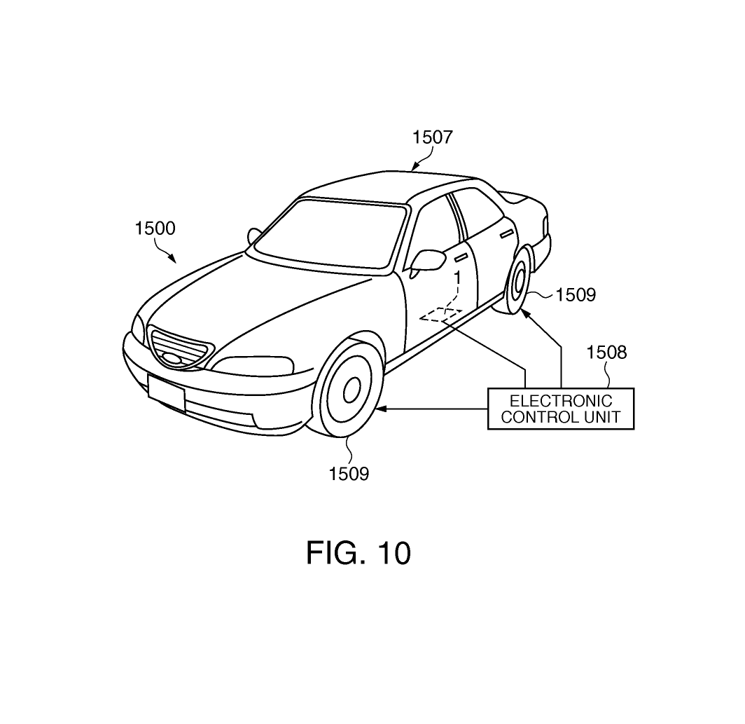

FIG. 10 is a perspective view schematically showing an automobile as an example of a mobile unit. An automobile 1500 is equipped with the electronic module 1 according to the embodiment of the invention. For example, as shown in FIG. 10, in the automobile 1500 as a mobile unit, electronic control units 1508 having the electronic module 1 arranged therein and controlling the inclination or the like of the automobile 1500 are installed on a vehicle body 1507. By using the electronic module 1 which is robust against vibration and temperature change in a mobile unit such as the automobile 1500 equipped with a number of electronic control units 1508, the degree of freedom in the installation position of the electronic control units 1508 can be increased. The electronic module 1 can also be applied to an electronic control unit (ECU) of a car navigation system, anti-lock braking system (ABS), airbag, engine control or the like.

The entire disclosure of Japanese Patent Application No. 2012-189631, filed Aug. 30, 2012 is expressly incorporated by reference herein.

What is claimed is:

1. An electronic module comprising:
a first substrate having a first surface on which a first sensor element is provided and a second surface on which a circuit element is provided;
wherein a shield layer is provided between the first sensor element and the circuit element.

2. The electronic module according to claim 1, comprising:
a second substrate provided with a second sensor element; and
a connecting portion which connects the first substrate and the second substrate with each other.

3. The electronic module according to claim 1, comprising a supporting portion having plural fixing surfaces,
wherein the first substrate is fixed to the fixing surface.

4. The electronic module according to claim 3, wherein the supporting portion has an opening which accommodates one of the first sensor element and the circuit element.

5. The electronic module according to claim 3, wherein the first sensor element is arranged on the side of the supporting portion, and the circuit element is arranged on the side opposite to the supporting portion.

6. The electronic module according to claim 5, comprising a pedestal for fixing the supporting portion thereon,
wherein the circuit element is fixed to the pedestal.

7. The electronic module according to claim 1, wherein the circuit element has a first circuit portion provided on the second surface and a second circuit portion provided on the first circuit portion, and
a separation layer is provided between the first circuit portion and the second circuit portion.

8. The electronic module according to claim 7, wherein the first circuit portion includes an analog circuit which amplifies an output signal from at least one of the first sensor element and the second sensor element, and
the second circuit portion includes a digital circuit which converts the output signal amplified by the analog circuit to a digital signal.

9. An electronic module comprising:
a first circuit portion; and
a second circuit portion stacked on the first circuit portion and electrically connected to the first circuit portion;
wherein a separation layer is provided between the first circuit portion and the second circuit portion.

10. An electronic device equipped with the electronic module according to claim 1.

11. An electronic device equipped with the electronic module according to claim 9.

12. A mobile unit equipped with the electronic module according to claim 1.

13. A mobile unit equipped with the electronic module according to claim 9.
